(19) United States
(12) Patent Application Publication
(10) Pub. No.: US 2026/0223756 A1
(43) Pub. Date: Jul. 30, 2026

(54) SEMICONDUCTOR MODULE AND POWER CONVERSION APPARATUS

(71) Applicant: MITSUBISHI ELECTRIC CORPORATION, Tokyo (JP)

(72) Inventors: Daichi YOSHO, Tokyo (JP); Kazuto MIKAMI, Tokyo (JP)

(21) Appl. No.: 19/147,684

(22) PCT Filed: Feb. 14, 2023
(86) PCT No.: PCT/JP2023/004892

§ 371 Date: Jul. 11, 2025

(51) Int. Cl. H10W 90/00; H10W 72/50; H10W 90/10

(52) U.S. Cl. CPC H10W 90/753; H10W 72/547; H10W 90/10; H10W 90/401; H10W 90/754

(57) ABSTRACT

A semiconductor module includes a first insulating substrate, a plurality of first semiconductor elements, and a conductive wire. The first insulating substrate includes a circuit pattern. The plurality of first semiconductor elements are arranged on the circuit pattern. The plurality of first semiconductor elements include a converter diode. The circuit pattern includes a main circuit pattern on which the converter diode is mounted and a signal circuit pattern electrically connected to a unit substrate. A length of the conductive wire between the converter diode and the signal circuit pattern is longer than a length of a longest side of the plurality of first semiconductor elements.

### TECHNICAL FIELD

The present disclosure relates to a semiconductor module and a power conversion apparatus.

### BACKGROUND ART

WO2019/044748 (PTL 1) discloses a semiconductor module.

### CITATION LIST

### Patent Literature

PTL 1: WO2019/044748

### SUMMARY OF INVENTION

### Technical Problem

An object of the present disclosure is to provide a semiconductor module and a power conversion apparatus that can achieve reduction of an unnecessary current that flows into a unit substrate electrically connected to the semiconductor module.

### Solution to Problem

A semiconductor module in the present disclosure includes a first insulating substrate, a plurality of first semiconductor elements, and a conductive wire. The first insulating substrate includes an insulating layer including a main surface and a circuit pattern arranged on the main surface of the insulating layer. The plurality of first semiconductor elements are arranged on the circuit pattern. The plurality of first semiconductor elements include a converter diode. The circuit pattern includes a main circuit pattern on which the converter diode is mounted and a signal circuit pattern electrically connected to a unit substrate. The conductive wire is bonded to the converter diode and the signal circuit pattern. A length of the conductive wire between the converter diode and the signal circuit pattern is longer than a length of a longest side of the plurality of first semiconductor elements in a plan view of the main surface of the insulating layer.

A power conversion apparatus in the present disclosure includes a main conversion circuit including the semiconductor module in the present disclosure, the main conversion circuit converting inputted electric power and outputting resultant electric power, and a control circuit to output to the main conversion circuit, a control signal to control the main conversion circuit.

### Advantageous Effects of Invention

According to the semiconductor module and the power conversion apparatus in the present disclosure, the unnecessary current that flows into the unit substrate electrically connected to the semiconductor module can be reduced.

### BRIEF DESCRIPTION OF DRAWINGS

FIG. 1 is a schematic diagram showing a semiconductor device in a first embodiment.

FIG. 2 is a schematic plan view of a semiconductor module in the first embodiment.

FIG. 3 is a schematic cross-sectional view of the semiconductor module in the first embodiment, along the line III-III shown in FIG. 2.

FIG. 4 is a circuit diagram of the semiconductor module in the first embodiment.

FIG. 5 is a block diagram showing a configuration of a power conversion system in a second embodiment.

FIG. 6 is a circuit diagram of the power conversion system in the second embodiment.

FIG. 7 is a schematic diagram of a main conversion circuit included in the power conversion system in the second embodiment.

FIG. 8 is a schematic plan view of a second semiconductor module included in the power conversion system in the second embodiment.

### DESCRIPTION OF EMBODIMENTS

Embodiments of the present disclosure will be described below. The same elements have the same reference characters allotted and description thereof will not be repeated.

### First Embodiment

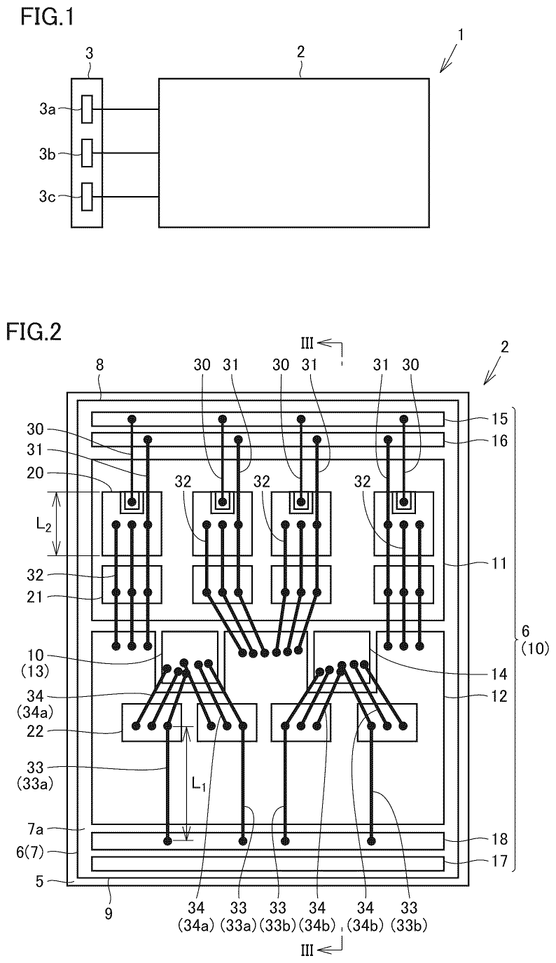

A semiconductor device 1 in a first embodiment will be described with reference to FIG. 1. Semiconductor device 1 includes a semiconductor module 2 and a unit substrate 3. Unit substrate 3 is, for example, a printed circuit board. Unit substrate 3 includes, for example, a gate voltage control circuit 3a, an emitter voltage control circuit 3b, and a monitoring circuit 3c. Gate voltage control circuit 3a controls a gate voltage to be applied to a gate electrode of a semiconductor element 20. Emitter voltage control circuit 3b controls an emitter voltage of semiconductor element 20. Monitoring circuit 3c senses a voltage of a semiconductor element 22 (more specifically, a cathode voltage of semiconductor element 22).

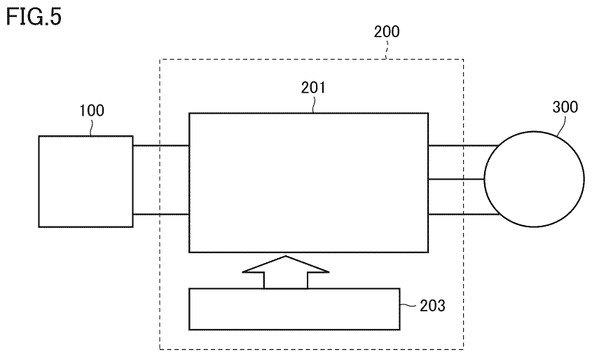

Semiconductor module 2 in the present embodiment will be described with reference to FIGS. 2 to 4. Semiconductor module 2 is, for example, a DC/DC converter. Semiconductor module 2 includes a base plate 5, an insulating substrate 6, a plurality of semiconductor elements 20, 21, and 22, conductive wires 30, 31, 32, 33, and 34, a casing 40, a sealing member 41, and an external electrode 45.

Base plate 5 is formed, for example, of metal such as Cu, an alloy such as CuMo, or a metal-based composite material such as AlSiC. Base plate 5 supports insulating substrate 6. Base plate 5 dissipates heat generated in the plurality of semiconductor elements 20, 21, and 22 to the outside of semiconductor module 2.

Insulating substrate 6 is arranged on base plate 5. Insulating substrate 6 includes an insulating layer 7 and a circuit pattern 10.

Insulating layer 7 may be formed of such ceramic as aluminum nitride (AlN), aluminum oxide (Al₂O₃), or silicon nitride (Si₃N₄). Insulating layer 7 may be formed of an organic insulating material obtained by dispersion of such a filler as silica, alumina, or boron nitride (BN) in binder resin such as epoxy resin or liquid crystal polymer. Insulating layer 7 includes a main surface 7a on a side opposite to a base plate 5 side. Insulating layer 7 includes an edge 8 and an edge 9 on a side opposite to edge 8.

Circuit pattern 10 is arranged on main surface 7a of insulating layer 7. Circuit pattern 10 is joined to insulating layer 7 by brazing or the like. Circuit pattern 10 is formed of metal such as copper. Circuit pattern 10 is, for example, a rolled copper foil. Circuit pattern 10 includes main circuit patterns 11 and 12, conductive pads 13 and 14, and signal circuit patterns 15, 16, 17, and 18.

Main circuit pattern 11 is arranged near edge 8 relative to main circuit pattern 12. Main circuit pattern 12 is distant from main circuit pattern 11 and arranged near edge 9 relative to main circuit pattern 11. External electrode 45 is connected to main circuit pattern 12. For example, external electrode 45 is an emitter main terminal of an upper arm (which will be described later) of semiconductor module 2 and also a cathode main terminal of a lower arm (which will be described later) of semiconductor module 2.

Conductive pads 13 and 14 are arranged between main circuit pattern 11 and main circuit pattern 12. Specifically, a recess is provided in an edge of main circuit pattern 12 opposed to main circuit pattern 11. Conductive pads 13 and 14 are arranged in the recess. Conductive pads 13 and 14 are distant from main circuit patterns 11 and 12. Conductive pads 13 and 14 are distant from each other. For example, an anode main terminal (not shown) of the lower arm (which will be described later) of semiconductor module 2 is connected to conductive pads 13 and 14.

Signal circuit patterns 15 and 16 are arranged near edge 8 relative to main circuit pattern 11. Signal circuit pattern 15 is electrically connected to the gate electrode of semiconductor element 20 and gate voltage control circuit 3a (see FIG. 1) of unit substrate 3 and functions as a gate control pattern. Signal circuit pattern 16 is distant from main circuit pattern 11 and signal circuit pattern 15 and arranged between main circuit pattern 11 and signal circuit pattern 15. Signal circuit pattern 16 is electrically connected to an emitter electrode of semiconductor element 20 and emitter voltage control circuit 3b (see FIG. 1) of unit substrate 3 and functions as an emitter control pattern. Signal circuit patterns 15 and 16 are, for example, conductors each in a form of a band.

Signal circuit patterns 17 and 18 are arranged near edge 9 relative to main circuit pattern 12. Signal circuit pattern 18 is electrically connected to an anode electrode of semiconductor element 22 and monitoring circuit 3c (see FIG. 1) of unit substrate 3. Signal circuit pattern 18 is distant from main circuit pattern 12 and signal circuit pattern 17 and arranged between main circuit pattern 12 and signal circuit pattern 17. Signal circuit pattern 17 may be identical in shape to signal circuit pattern 15. Signal circuit pattern 18 may be identical in shape to signal circuit pattern 16. Signal circuit patterns 17 and 18 are, for example, conductors each in a form of a band.

The plurality of semiconductor elements 20, 21, and 22 are arranged on circuit pattern 10. Specifically, semiconductor elements 20 and 21 are mounted on main circuit pattern 11. Semiconductor elements 20 and 21 implement the upper arm of semiconductor module 2. Semiconductor element 22 is mounted on main circuit pattern 12. Semiconductor element 22 implements the lower arm of semiconductor module 2.

Semiconductor element 20 is a switching element such as an insulated gate bipolar transistor (IGBT). Semiconductor element 20 includes the gate electrode, the emitter electrode, and a collector electrode. The collector electrode is joined to main circuit pattern 11 with a conductive bonding member such as solder such as leadfree solder or a metallic fine particulate sintered material such as a silver nanoparticulate sintered material.

Semiconductor element 21 is a freewheeling element such as a diode. Semiconductor element 21 includes an anode electrode and a cathode electrode. The cathode electrode of semiconductor element 21 is joined to main circuit pattern 11 with a conductive bonding member such as solder such as leadfree solder or a metallic fine particulate sintered material such as a silver nanoparticulate sintered material. Each of semiconductor elements 21 is connected in antiparallel to corresponding one of semiconductor elements 20.

Semiconductor element 22 is a converter diode. Semiconductor element 22 includes the anode electrode and a cathode electrode. The cathode electrode of semiconductor element 22 is joined to main circuit pattern 12 with a conductive bonding member such as solder such as leadfree solder or a metallic fine particulate sintered material such as a silver nanoparticulate sintered material.

Conductive wires 30, 31, 32, 33, and 34 are each, for example, a metallic wire such as an Al wire, an Au wire, or a Cu wire. Through conductive wires 31, 32, 33, and 34, currents more than currents through conductive wires 30 flow. Therefore, each of conductive wires 31, 32, 33, and 34 is larger in diameter than each of conductive wires 30.

Conductive wire 30 is bonded to signal circuit pattern 15 and the gate electrode of semiconductor element 20.

Conductive wire 31 is bonded to signal circuit pattern 16, the emitter electrode of semiconductor element 20, the anode electrode of semiconductor element 21, and main circuit pattern 12. Conductive wire 31 is continuously routed to signal circuit pattern 16, the emitter electrode of semiconductor element 20, the anode electrode of semiconductor element 21, and main circuit pattern 12.

Conductive wire 32 is bonded to the emitter electrode of semiconductor element 20, the anode electrode of semiconductor element 21, and main circuit pattern 12. Conductive wire 32 is continuously routed to the emitter electrode of semiconductor element 20, the anode electrode of semiconductor element 21, and main circuit pattern 12.

Conductive wire 33 includes a conductive wire 33a and a conductive wire 33b. Conductive wire 33a is bonded to conductive pad 13, the anode electrode of semiconductor element 22, and signal circuit pattern 18. Conductive wire 33a is continuously routed to conductive pad 13, the anode electrode of semiconductor element 22, and signal circuit pattern 18. Conductive wire 33b is bonded to conductive pad 14, the anode electrode of semiconductor element 22, and signal circuit pattern 18. Conductive wire 33b is continuously routed to conductive pad 14, the anode electrode of semiconductor element 22, and signal circuit pattern 18. A portion of conductive wire 33 located between semiconductor element 22 which is the converter diode and signal circuit pattern 18 functions as wiring for monitoring.

Conductive wire 34 includes a conductive wire 34a and a conductive wire 34b. Conductive wire 34a is bonded to conductive pad 13 and the anode electrode of semiconductor element 22. Conductive wire 34b is bonded to conductive pad 14 and the anode electrode of semiconductor element 22.

A length L₁ of conductive wire 33 between semiconductor element 22 which is the converter diode and signal circuit pattern 18 is longer than length L₂ of a longest side of the plurality of semiconductor elements 20, 21, and 22 in the plan view of main surface 7a of insulating layer 7. Length L₁ is a length between a first bonded portion of conductive wire 33 bonded to semiconductor element 22 and a second bonded portion of conductive wire 33 bonded to signal circuit pattern 18. In the present embodiment, in the plan view of main surface 7a of insulating layer 7, semiconductor element 20 among semiconductor elements 20, 21, and 22 has the longest side. Therefore, length L₂ is the length of the longest side of semiconductor element 20 in the plan view of main surface 7a of insulating layer 7. Length L₁ of conductive wire 33 is equal to or longer than 25 mm.

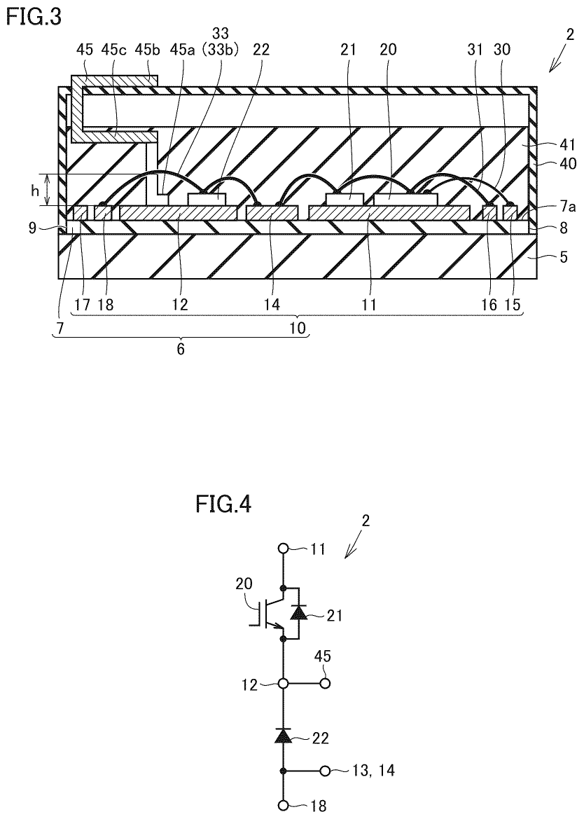

Referring to FIG. 3, casing 40 is formed of insulating resin such as polyphenylene sulfide resin (PPS), polybutylene terephthalate resin (PBT), or polyethylene terephthalate resin (PET). Casing 40 is fixed to base plate 5 with an adhesive (not shown) or the like. Insulating substrate 6, the plurality of semiconductor elements 20, 21, and 22, conductive wires 30, 31, 32, 33, and 34, and sealing member 41 are accommodated inside base plate 5 and casing 40.

The plurality of semiconductor elements 20, 21, and 22 are sealed with sealing member 41. Conductive wires 30, 31, 32, 33, and 34 may further be sealed with sealing member 41. Sealing member 41 is formed of insulating resin such as epoxy resin or silicone gel. A filler may be dispersed in the insulating resin for sealing member 41.

External electrode 45 is formed, for example, of metal such as copper. External electrode 45 includes an end 45a and an end 45b opposite to end 45a. End 45a of external electrode 45 is joined to main circuit pattern 12. End 45a of external electrode 45 is located outside casing 40. External electrode 45 passes through casing 40. External electrode 45 includes a horizontally extending portion 45c that extends along main surface 7a of insulating layer 7.

In semiconductor module 2, a largest height h of conductive wire 33 from main circuit pattern 12 is equal to or smaller than 3 mm. Therefore, while an insulating distance between horizontally extending portion 45c of external electrode 45 and conductive wire 33 is ensured, horizontally extending portion 45c of external electrode 45 can be brought closer to main circuit pattern 12. The height of semiconductor module 2 may be made smaller. Semiconductor module 2 may be reduced in size. The height of sealing member 41 may be made smaller. An amount of use of sealing member 41 may be made smaller and cost for semiconductor module 2 may be reduced.

Operations and functions of semiconductor module 2 in the present embodiment will be described.

A first direct-current (DC) voltage is inputted from an external power supply (not shown) to main circuit pattern 11. Gate voltage control circuit 3a and emitter voltage control circuit 3b control semiconductor element 20 which is the switching element, so that a second DC voltage different from the first DC voltage is outputted from external electrode 45. Semiconductor element 22 which is the converter diode is connected to monitoring circuit 3c through conductive wire 33 and signal circuit pattern 18. Monitoring circuit 3c senses the voltage of semiconductor element 22.

Length L₁ of conductive wire 33 between semiconductor element 22 which is the converter diode and signal circuit pattern 18 is longer than length L₂ of the longest side of the plurality of semiconductor elements 20, 21, and 22 in the plan view of main surface 7a of insulating layer 7. Therefore, an electrical resistance of a portion of conductive wire 33 between semiconductor element 22 which is the converter diode and signal circuit pattern 18 increases. An unnecessary current that flows into unit substrate 3 through conductive wire 33 and signal circuit pattern 18 decreases. Generation of heat in unit substrate 3 originating from the unnecessary current can be suppressed and damage to unit substrate 3 by heat can be prevented. Voltage lowering in the portion of conductive wire 33 between semiconductor element 22 and signal circuit pattern 18 due to the unnecessary current is lessened. Therefore, the voltage of semiconductor element 22 can more accurately be sensed with monitoring circuit 3c.

Effects of semiconductor module 2 in the present embodiment will be described.

Semiconductor module 2 in the present embodiment includes a first insulating substrate (insulating substrate 6), a plurality of first semiconductor elements (semiconductor elements 20, 21, and 22), and conductive wire 33. The first insulating substrate includes insulating layer 7 including main surface 7a and circuit pattern 10 arranged on main surface 7a of insulating layer 7. The plurality of first semiconductor elements are arranged on circuit pattern 10. The plurality of first semiconductor elements include the converter diode (semiconductor element 22). Circuit pattern 10 includes main circuit pattern 12 on which the converter diode is mounted and signal circuit pattern 18 electrically connected to unit substrate 3. Conductive wire 33 is bonded to the converter diode and signal circuit pattern 18. Length L₁ of conductive wire 33 between the converter diode and signal circuit pattern 18 is longer than length L₂ of the longest side of the plurality of first semiconductor elements in the plan view of main surface 7a of insulating layer 7.

Therefore, the electrical resistance of conductive wire 33 between the converter diode (semiconductor element 22) and signal circuit pattern 18 increases. The unnecessary current that flows into unit substrate 3 through conductive wire 33 and signal circuit pattern 18 decreases. Generation of heat in unit substrate 3 originating from the unnecessary current can be suppressed and damage to unit substrate 3 by heat can be prevented. Voltage lowering in conductive wire 33 due to the unnecessary current is lessened. Therefore, the voltage of semiconductor element 22 can more accurately be sensed with monitoring circuit 3c.

In semiconductor module 2 in the present embodiment, length L₁ of conductive wire 33 between the converter diode (semiconductor element 22) and signal circuit pattern 18 is equal to or longer than 25 mm.

Therefore, the electrical resistance of conductive wire 33 between the converter diode (semiconductor element 22) and signal circuit pattern 18 increases. The unnecessary current that flows into unit substrate 3 through conductive wire 33 and signal circuit pattern 18 decreases. Generation of heat in unit substrate 3 originating from the unnecessary current can be suppressed and damage to unit substrate 3 by heat can be prevented. Voltage lowering in conductive wire 33 due to the unnecessary current is lessened. Therefore, the voltage of semiconductor element 22 can more accurately be sensed with monitoring circuit 3c.

In semiconductor module 2 in the present embodiment, largest height h of conductive wire 33 from main circuit pattern 12 is equal to or smaller than 3 mm.

Therefore, the height of semiconductor module 2 is made smaller. Semiconductor module 2 can be reduced in size.

In semiconductor module 2 in the present embodiment, circuit pattern 10 includes conductive pad 13. Conductive wire 33 is bonded also to conductive pad 13. Conductive wire 33 is continuously routed to conductive pad 13, the converter diode (semiconductor element 22), and signal circuit pattern 18.

Therefore, the number of times of bonding of conductive wire 33 to the converter diode (semiconductor element 22) decreases. Damage to the converter diode at the time of bonding of conductive wire 33 to the converter diode may be lessened. Since a space necessary for routing of conductive wire 33 is reduced, semiconductor module 2 can be reduced in size.

### Second Embodiment

The present embodiment is application of semiconductor module 2 in the first embodiment described above to a power conversion apparatus. The present disclosure is not limited to a specific power conversion apparatus, and an example in which semiconductor module 2 in the present disclosure is applied to a three-phase inverter will be described below as a second embodiment.

A power conversion system shown in FIG. 5 is constituted of a power supply 100, a power conversion apparatus 200, and a load 300. Power supply 100 is a DC power supply and supplies DC power to power conversion apparatus 200. Though power supply 100 is not particularly limited, it may be implemented, for example, by a DC system, a photovoltaic cell, or a storage battery, or a rectification circuit or an AC/DC converter connected to an alternating-current (AC) system. Power supply 100 may be implemented by a DC/DC converter to convert DC power outputted from the DC system to prescribed electric power.

Power conversion apparatus 200 is a three-phase inverter connected between power supply 100 and load 300, and it converts DC power supplied from power supply 100 to AC power and supplies resultant AC power to load 300. As shown in FIG. 5, power conversion apparatus 200 includes a main conversion circuit 201 to convert DC power to AC power and output resultant AC power and a control circuit 203 to output to main conversion circuit 201, a control signal to control main conversion circuit 201.

Load 300 is a three-phase motor driven with AC power supplied from power conversion apparatus 200. Usage of load 300 is not limited to specific usage. Load 300 is a motor to be mounted on various electrical appliances and used, for example, as a motor for a hybrid vehicle, an electric vehicle, a rail vehicle, an elevator, or an air-conditioner.

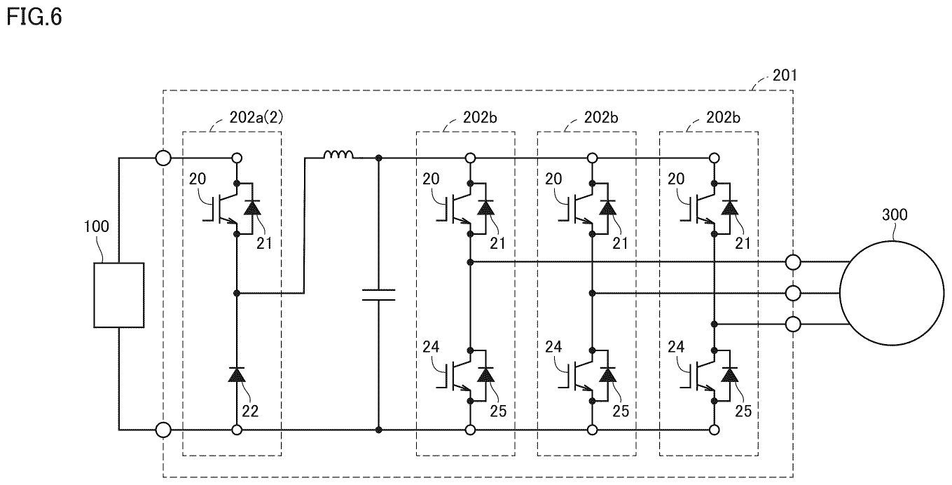

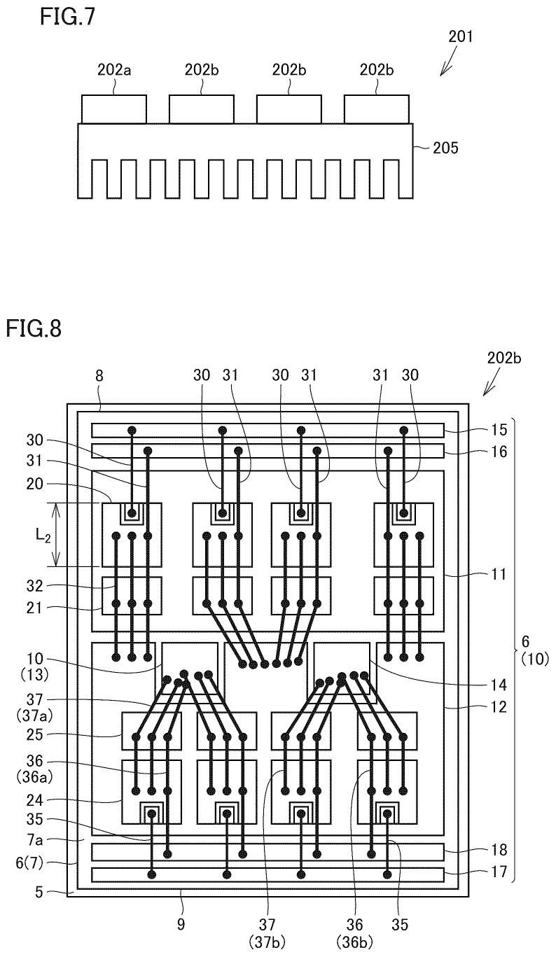

Details of power conversion apparatus 200 will be described below. As shown in FIGS. 6 and 7, main conversion circuit 201 includes a semiconductor module 202a, a semiconductor module 202b, and a heat sink 205. Semiconductor module 202a is semiconductor module 2 in the first embodiment. Semiconductor module 202b is, for example, an inverter to convert a DC voltage outputted from semiconductor module 202a to an AC voltage.

Referring to FIGS. 6 and 8, semiconductor module 202b includes base plate 5, insulating substrate 6, a plurality of semiconductor elements 20, 21, 24, and 25, and conductive wires 30, 31, 32, 35, 36, and 37.

Base plate 5 (see FIG. 8) of semiconductor module 202b is identical to base plate 5 (FIGS. 2 and 3) of semiconductor module 202a. Semiconductor module 202a and semiconductor module 202b are mounted on heat sink 205. Specifically, base plate 5 of semiconductor module 202b and base plate 5 of semiconductor module 202a are joined to heat sink 205. Insulating substrate 6 (see FIG. 8) of semiconductor module 202b is identical to insulating substrate 6 (FIGS. 2 and 3) of semiconductor module 202a. Base plate 5 and insulating substrate 6 are used in semiconductor module 202a and semiconductor module 202b.

Semiconductor elements 20 and 21 of semiconductor module 202b are identical to semiconductor elements 20 and 21 of semiconductor module 202a. Conductive wires 30, 31, and 32 of semiconductor module 202b are identical to conductive wires 30, 31, and 32 of semiconductor module 202a.

Semiconductor device 24 is a switching element such as an insulated gate bipolar transistor (IGBT) similarly to semiconductor element 20. Semiconductor element 24 includes a gate electrode, an emitter electrode, and a collector electrode. The collector electrode is joined to main circuit pattern 12 with a conductive bonding member such as solder such as leadfree solder or a metallic fine particulate sintered material such as a silver nanoparticulate sintered material.

Semiconductor element 25 is a freewheeling element such as a diode, similarly to semiconductor element 21. Semiconductor element 25 includes an anode electrode and a cathode electrode. The cathode electrode of semiconductor element 25 is joined to main circuit pattern 12 with a conductive bonding member such as solder such as leadfree solder or a metallic fine particulate sintered material such as a silver nanoparticulate sintered material. Each of semiconductor elements 25 is connected in antiparallel to corresponding one of semiconductor elements 24.

Conductive wires 35, 36, and 37 are each, for example, a metallic wire such as an Al wire, an Au wire, or a Cu wire, similarly to conductive wires 30, 31, 32, 33, and 34. Through conductive wires 36 and 37, currents more than currents through conductive wires 35 flow. Therefore, each of conductive wires 36 and 37 is larger in diameter than each of conductive wires 35.

Conductive wire 35 is bonded to signal circuit pattern 17 and the gate electrode of semiconductor element 24. Signal circuit pattern 17 is electrically connected to the gate electrode of semiconductor element 24 and gate voltage control circuit 3a of unit substrate 3 and functions as the gate control pattern. Gate voltage control circuit 3a controls a gate voltage to be applied to the gate electrode of semiconductor element 24.

Conductive wire 36 includes a conductive wire 36a and a conductive wire 36b. Conductive wire 36a is bonded to signal circuit pattern 18, the emitter electrode of semiconductor element 24, the anode electrode of semiconductor element 25, and conductive pad 13. Conductive wire 36a is continuously routed to signal circuit pattern 18, the emitter electrode of semiconductor element 24, the anode electrode of semiconductor element 25, and conductive pad 13. Conductive wire 36b is bonded to signal circuit pattern 18, the emitter electrode of semiconductor element 24, the anode electrode of semiconductor element 25, and conductive pad 14. Conductive wire 36b is continuously routed to signal circuit pattern 18, the emitter electrode of semiconductor element 24, the anode electrode of semiconductor element 25, and conductive pad 14.

Signal circuit pattern 18 is electrically connected to the emitter electrode of semiconductor element 24 and emitter voltage control circuit 3b of unit substrate 3 and functions as the emitter control pattern. Emitter voltage control circuit 3b controls the emitter voltage of semiconductor element 24.

Conductive wire 37 includes a conductive wire 37a and a conductive wire 37b. Conductive wire 37a is bonded to the emitter electrode of semiconductor element 24, the anode electrode of semiconductor element 25, and conductive pad 13. Conductive wire 37a is continuously routed to the emitter electrode of semiconductor element 24, the anode electrode of semiconductor element 25, and conductive pad 13. Conductive wire 37b is bonded to the emitter electrode of semiconductor element 24, the anode electrode of semiconductor element 25, and conductive pad 14. Conductive wire 37b is continuously routed to the emitter electrode of semiconductor element 24, the anode electrode of semiconductor element 25, and conductive pad 14.

The number of semiconductor elements 20, 21, 24, and 25 included in semiconductor module 202b is different from the number of semiconductor elements 20, 21, and 22 included in semiconductor module 202a. In the present embodiment, the number of semiconductor elements 20, 21, 24, and 25 included in semiconductor module 202b is larger than the number of semiconductor elements 20, 21, and 22 included in semiconductor module 202a.

As semiconductor elements 20 and 24 of semiconductor module 202b switch the DC voltage supplied from semiconductor module 202a, semiconductor module 202b converts DC power supplied from semiconductor module 202a to AC power and supplies resultant AC power to load 300. Main conversion circuit 201 in the present embodiment is a two-level three-phase full-bridge circuit. Semiconductor elements 20 and 21 of semiconductor module 202b implement the upper arm of semiconductor module 202b. Semiconductor elements 24 and 25 implement the lower arm of semiconductor module 202b. The upper and lower arms of semiconductor module 202b implement phases of the full-bridge circuit (the U phase, the V phase, and the W phase). Output terminals of the upper and lower arms, that is, three output terminals of main conversion circuit 201, are connected to load 300.

Main conversion circuit 201 includes a drive circuit (not shown) to drive the switching element (semiconductor elements 20 and 24). Unit substrate 3 (see FIG. 1) includes the drive circuit. The drive circuit generates a drive signal to drive the switching element included in main conversion circuit 201 and supplies the drive signal to a control electrode of the switching element of main conversion circuit 201. Specifically, in accordance with the control signal from control circuit 203, the drive circuit outputs the drive signal to set the switching element to on and the drive signal to set the switching element to off to the control electrode of each switching element.

Control circuit 203 controls the switching element (semiconductor elements 20 and 24) of main conversion circuit 201 such that electric power is supplied to load 300. Specifically, the control circuit calculates a time period (an on time period) for which each switching element of main conversion circuit 201 should be on, based on electric power to be supplied to load 300. For example, main conversion circuit 201 can be controlled under PWM control to modulate the on time period of the switching element in accordance with a voltage to be outputted to load 300. Then, the control circuit outputs a control command (control signal) to the drive circuit included in main conversion circuit 201 such that, at each time point, an on signal is outputted to the switching element to be set to on and an off signal is outputted to the switching element to be set to off. The drive circuit outputs the on signal or the off signal as the drive signal, to the control electrode of each switching element, in accordance with this control signal. Unit substrate 3 (see FIG. 1) includes control circuit 203.

Though the example in which the present disclosure is applied to the two-level three-phase inverter is described in the present embodiment, without being limited as such, the present disclosure is applicable to various power conversion apparatuses. Though the two-level power conversion apparatus is described in the present embodiment, the power conversion apparatus may be a three-level power conversion apparatus or a multi-level power conversion apparatus. In an example where the power conversion apparatus supplies electric power to a single-phase load, the present disclosure may be applied to a single-phase inverter. In an example where the power conversion apparatus supplies electric power to a DC load or the like, the present disclosure may be applied to a DC/DC converter or an AC/DC converter.

The power conversion apparatus to which the present disclosure is applied is not limited to an above-described example in which a motor is adopted as the load, and the power conversion apparatus can also be incorporated, for example, in a power supply apparatus of an electro-discharge machine or a laser drilling machine or a power supply apparatus of an induction heating cooker or a wireless power transfer system. The power conversion apparatus to which the present disclosure is applied can further be used as a power conditioner of a photovoltaic power system or a power storage system.

Power conversion apparatus 200 in the present embodiment achieve effects below.

Power conversion apparatus 200 in the present embodiment includes main conversion circuit 201 including a first semiconductor module (semiconductor module 202a) which is semiconductor module 2 in the first embodiment, main conversion circuit 201 converting inputted electric power and outputting resultant electric power, and control circuit 203 to output to main conversion circuit 201, the control signal to control the main conversion circuit.

Therefore, the unnecessary current that flows into unit substrate 3 through conductive wire 33 and signal circuit pattern 18 decreases. Generation of heat in unit substrate 3 originating from the unnecessary current can be suppressed and damage to unit substrate 3 by heat can be prevented. The voltage of semiconductor element 22 can more accurately be sensed with monitoring circuit 3c.

In power conversion apparatus 200 in the present embodiment, main conversion circuit 201 further includes a second semiconductor module (semiconductor module 202b). The second semiconductor module includes a second insulating substrate (insulating substrate 6) identical to the first insulating substrate (insulating substrate 6) of the first semiconductor module and a plurality of second semiconductor elements (semiconductor elements 20, 21, 24, and 25). The number of the plurality of second semiconductor elements is different from the number of the plurality of first semiconductor elements (semiconductor elements 20, 21, and 22).

The second insulating substrate (insulating substrate 6) of the second semiconductor module (semiconductor module 202b) is identical to the first insulating substrate (insulating substrate 6) of the first semiconductor module (semiconductor module 202a). Simply by changing the number of semiconductor elements to be mounted on insulating substrate 6, the function (for example, the inverter) of the second semiconductor module can be different from the function (for example, the DC/DC converter) of the first semiconductor module. Cost for power conversion apparatus 200 can be reduced.

It should be understood that the first embodiment and the second embodiment disclosed herein are illustrative and non-restrictive in every respect. The scope of the present disclosure is defined by the terms of the claims rather than the description above and is intended to include any modifications within the scope and meaning equivalent to the terms of the claims.

### REFERENCE SIGNS LIST

1 semiconductor device; 2 semiconductor module; 3 unit substrate; 3a gate voltage control circuit; 3b emitter voltage control circuit; 3c monitoring circuit; 5 base plate; 6 insulating substrate; 7 insulating layer; 7a main surface; 8, 9 edge; 10 circuit pattern; 11, 12 main circuit pattern; 13, 14 conductive pad; 15, 16, 17, 18 signal circuit pattern; 20, 21, 22, 24, 25 semiconductor element; 30, 31, 32, 33, 33a, 33b, 34, 34a, 34b, 35, 36, 36a, 36b, 37, 37a, 37b conductive wire; 40 casing; 41 sealing member; 45 external electrode; 45a, 45b end; 45c horizontally extending portion; 100 power supply; 200 power conversion apparatus; 201 main conversion circuit; 202a, 202b semiconductor module; 203 control circuit; 205 heat sink; 300 load.

1. A semiconductor module comprising:
a first insulating substrate including an insulating layer including a main surface and a circuit pattern arranged on the main surface;
a plurality of first semiconductor elements arranged on the circuit pattern; and
a conductive wire, wherein
the plurality of first semiconductor elements include a converter diode,
the circuit pattern includes a main circuit pattern on which the converter diode is mounted and a signal circuit pattern electrically connected to a unit substrate,
the conductive wire is bonded to the converter diode and the signal circuit pattern, and
a length of the conductive wire between the converter diode and the signal circuit pattern is longer than a length of a longest side of the plurality of first semiconductor elements in a plan view of the main surface.

2. The semiconductor module according to claim 1, wherein
the length of the conductive wire between the converter diode and the signal circuit pattern is equal to or longer than 25 mm.

3. The semiconductor module according to claim 1, wherein
a maximum height of the conductive wire from the main circuit pattern is equal to or smaller than 3 mm.

4. The semiconductor module according to claim 1, wherein
the circuit pattern includes a conductive pad,
the conductive wire is bonded also to the conductive pad, and
the conductive wire is continuously routed to the conductive pad, the converter diode, and the signal circuit pattern.

5. A power conversion apparatus comprising:
a main conversion circuit including a first semiconductor module which is the semiconductor module according to of claim 1, the main conversion circuit converting inputted electric power and outputting resultant electric power; and
a control circuit to output to the main conversion circuit, a control signal to control the main conversion circuit.

6. The power conversion apparatus according to claim 5, wherein
the main conversion circuit further includes a second semiconductor module,
the second semiconductor module includes a second insulating substrate identical to the first insulating substrate of the first semiconductor module and a plurality of second semiconductor elements, and
the number of the plurality of second semiconductor elements is different from the number of the plurality of first semiconductor elements.
